(19) United States
(12) Patent Application Publication
(10) Pub. No.: US 2025/0210121 A1
(43) Pub. Date: Jun. 26, 2025

(54) MAGNETIC MEMORY DEVICE

(71) Applicant: SAMSUNG ELECTRONICS CO., LTD., Suwon-si (KR)

(72) Inventors: Stuart Papworth Parkin, München (DE); Andrea Migliorini, München (DE); Jaechun Jeon, München (DE); Ung Hwan Pi, Hwaseong-si (KR)

(73) Assignee: Max-Planck-Gesellschaft zur Förderung der Wissenschaften e.V., München (DE)

(21) Appl. No.: 18/953,964

(22) Filed: Nov. 20, 2024

(30) Foreign Application Priority Data
Dec. 21, 2023 (KR) 10-2023-0187944

(51) Int. Cl. G11C 19/08; G11C 11/16; H01F 10/32; H10B 61/00; H10N 50/10; H10N 50/80

(52) U.S. Cl. CPC G11C 19/0841; G11C 11/161; G11C 11/1673; G11C 11/1675; H01F 10/3286; H10B 61/00; H10N 50/10; H10N 50/80

(57) ABSTRACT

A magnetic memory device includes a conductive line extended in a first direction, a magnetic track line provided on the conductive line and extended in the first direction, and a non-magnetic line provided on the magnetic track line and extended in the first direction. The magnetic track line includes a lower magnetic layer and an upper magnetic layer stacked on the conductive line, an exchange coupling layer between the lower and upper magnetic layers, and a spacer layer between the exchange coupling layer and the upper magnetic layer. The exchange coupling layer is in contact with a bottom surface of the spacer layer, and the lower and upper magnetic layers are antiferromagnetically coupled with each other by the exchange coupling layer.

### CROSS-REFERENCE TO RELATED APPLICATION(S)

This U.S. non-provisional patent application claims priority under 35 U.S.C. § 119 to Korean Patent Application No. 10-2023-0187944, filed on Dec. 21, 2023, in the Korean Intellectual Property Office, the entire contents of which are hereby incorporated by reference.

### BACKGROUND

Due to the increased demand for electronic devices with a fast speed and/or a low power consumption, memory devices embedded in the electronic devices can benefit from a fast operating speed and/or a low operating voltage.

### SUMMARY

The present disclosure relates to a magnetic memory device, and in particular, to a magnetic memory device using movement of a magnetic domain wall.

A magnetic memory device is being developed to meet various demands, such as reduced latency and/or non-volatility.

The magnetic domain memory device has a magnetic track line including a plurality of magnetic domains, and the direction of the movement of the magnetic domains in the magnetic track line is changed depending on the direction of a current. A reading and writing device is provided near the magnetic track line to perform operations of reading and writing data from and in the magnetic domains. For example, a magnetic tunnel junction may be used as the reading and writing device. Various studies have been conducted to reduce a current, which is required to move the magnetic domains, and to improve the tunnel magnetoresistance characteristics of the magnetic tunnel junction.

This disclosure describes a magnetic memory device, which includes a magnetic track line with high domain movement efficiency.

This disclosure describes a magnetic memory device, in which a magnetic tunnel junction with improved tunnel magnetoresistance characteristics is used as a reading device.

An example magnetic memory device may include a conductive line extended in a first direction, a magnetic track line provided on the conductive line and extended in the first direction, and a non-magnetic line provided on the magnetic track line and extended in the first direction. The magnetic track line may include a lower magnetic layer and an upper magnetic layer stacked on the conductive line, an exchange coupling layer between the lower and upper magnetic layers, and a spacer layer between the exchange coupling layer and the upper magnetic layer. The exchange coupling layer may be in contact with a bottom surface of the spacer layer, and the lower and upper magnetic layers may be antiferromagnetically coupled with each other by the exchange coupling layer.

An example magnetic memory device may include a conductive line extended in a first direction, a magnetic track line provided on a top surface of the conductive line and extended in the first direction, and a reference magnetic pattern on the magnetic track line. The magnetic track line may include a lower magnetic layer and an upper magnetic layer stacked on the conductive line, an exchange coupling layer between the lower and upper magnetic layers, and a spacer layer between the exchange coupling layer and the upper magnetic layer. A bottom surface of the spacer layer may be in contact with the exchange coupling layer, and a top surface of the spacer layer may be in contact with the upper magnetic layer. The lower and upper magnetic layers may be antiferromagnetically coupled with each other by the exchange coupling layer.

### BRIEF DESCRIPTION OF THE DRAWINGS

FIG. 1 is a perspective view schematically illustrating an example magnetic memory device.

FIG. 2 is a sectional view taken along a line I-I′ of FIG. 1.

FIGS. 3A, 3B, 4A, and 4B are sectional views illustrating an example method of fabricating a magnetic memory device, FIGS. 3A and 4A are sectional views corresponding to the line I-I′ of FIG. 1, and FIGS. 3B and 4B are sectional views corresponding to a line II-II′ of FIG. 1.

FIGS. 5A and 5B are sectional views, which are taken along a line I-I′ of FIG. 1 to illustrate a magnetic memory device.

FIG. 6A is a plan view illustrating an example magnetic memory device, and FIG. 6B is a sectional view taken along a line III-III′ of FIG. 6A.

FIG. 7A is a plan view illustrating an example magnetic memory device, and FIG. 7B is a sectional view taken along a line III-III′ of FIG. 7A.

FIG. 8A is a plan view illustrating an example magnetic memory device, and FIG. 8B is a sectional view taken along a line III-III′ of FIG. 8A.

FIG. 9A is a plan view illustrating an example magnetic memory device, and FIG. 9B is a sectional view taken along a line III-III′ of FIG. 9A.

### DETAILED DESCRIPTION

Example implementations will now be described more fully with reference to the accompanying drawings, in which example implementations are shown.

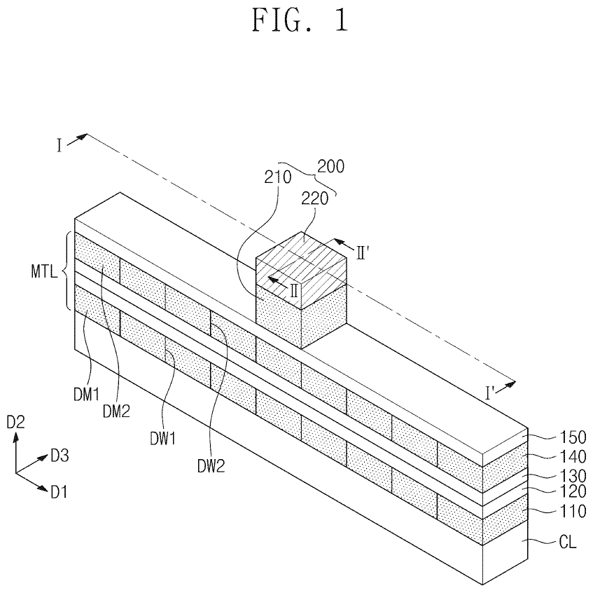

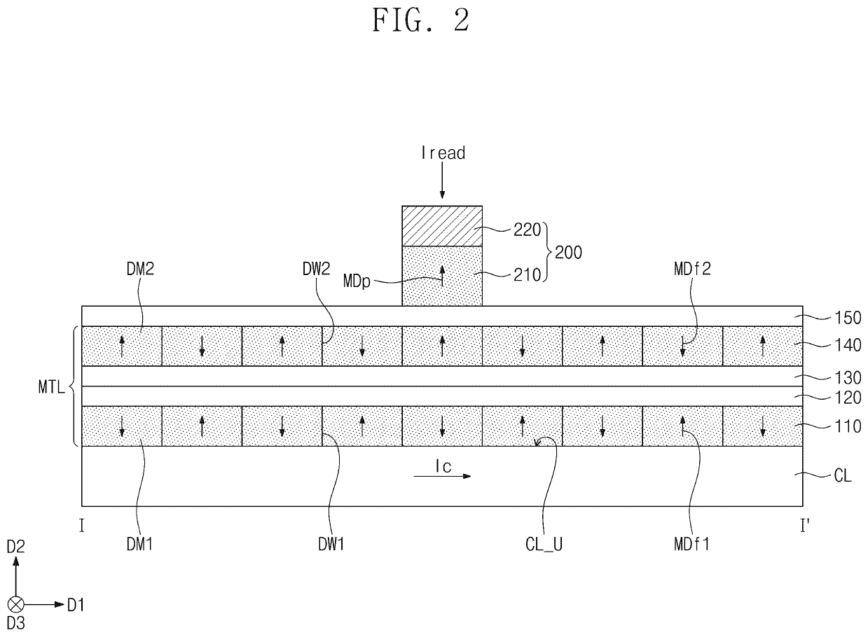

FIG. 1 is a perspective view schematically illustrating a magnetic memory device. FIG. 2 is a sectional view taken along a line I-I′ of FIG. 1.

Referring to FIGS. 1 and 2, the magnetic memory device may include a conductive line CL, a magnetic track line MTL on the conductive line CL, a non-magnetic line 150 on the magnetic track line MTL, and a reading device 200 on the non-magnetic line 150. The conductive line CL may be extended in a first direction D1, which is parallel to a top surface CL_U of the conductive line CL. The magnetic track line MTL and the non-magnetic line 150 may be sequentially stacked on the top surface CL_U of the conductive line CL in a second direction D2, which is perpendicular to the top surface CL_U of the conductive line CL. The magnetic track line MTL may be interposed between the conductive line CL and the non-magnetic line 150. The magnetic track line MTL and the non-magnetic line 150 may be extended in the first direction D1. Each of the conductive line CL, the magnetic track line MTL, and the non-magnetic line 150 may have a width in a third direction D3, which is parallel to the top surface CL_U of the conductive line CL and is not parallel to the first direction D1, and each of the conductive line CL, the magnetic track line MTL, and the non-magnetic line 150 may be a line-shaped pattern with a length in the first direction D1 that is larger than its width in the third direction D3. The third direction D3 may be perpendicular to the first direction D1. The reading device 200 may be disposed adjacent to a portion of the non-magnetic line 150.

The conductive line CL may be configured to produce a spin orbit torque by a current Ic passing through the same. The current Ic may be an in-plane current, which flows through the conductive line CL in the first direction D1 or in the opposite direction of the first direction D1. The conductive line CL may include a material producing a spin Hall effect or a Rashba effect, when there is the current Ic flowing through the conductive line CL. The conductive line CL may include heavy metals with an atomic number of 30 or higher and may include at least one of iridium (Ir), ruthenium (Ru), tantalum (Ta), platinum (Pt), palladium (Pd), bismuth (Bi), hafnium (Hf), titanium (Ti), tungsten (W), or alloys thereof. In an implementation, the conductive line CL may include a topological insulator containing Bi, Se, Te, or Sb.

The magnetic track line MTL may include a lower magnetic layer 110, an exchange coupling layer 120, a spacer layer 130, and an upper magnetic layer 140, which are sequentially stacked on the conductive line CL. The lower magnetic layer 110, the exchange coupling layer 120, the spacer layer 130, and the upper magnetic layer 140 may be sequentially stacked on the top surface CL_U of the conductive line CL in the second direction D2. The lower magnetic layer 110 may be interposed between the conductive line CL and the exchange coupling layer 120, and the exchange coupling layer 120 may be interposed between the lower magnetic layer 110 and the spacer layer 130. The spacer layer 130 may be interposed between the exchange coupling layer 120 and the upper magnetic layer 140. Each of the lower magnetic layer 110, the exchange coupling layer 120, the spacer layer 130, and the upper magnetic layer 140 may be a line-shaped pattern that is extended in the first direction D1. Each of the conductive line CL and the magnetic track line MTL may be a line-shaped pattern that is extended in the first direction D1, but the inventive concept is not limited to this example. For example, the conductive line CL and the magnetic track line MTL may be U-shaped line patterns.

The lower magnetic layer 110 may include lower magnetic domains DM1, which are arranged in the first direction D1, and lower magnetic domain walls DW1, which are provided between the lower magnetic domains DM1. Each of the lower magnetic domains DM1 may be a region, which is formed in the lower magnetic layer 110 and has a magnetic moment of the same or aligned direction, and each of the lower magnetic domain walls DW1 may be a boundary formed between the lower magnetic domains DM1, where the direction of the magnetic moment is changed. The lower magnetic domains DM1 and the lower magnetic domain walls DW1 may be alternatingly arranged in the first direction D1. A bottom surface of the lower magnetic layer 110 may be in contact with the conductive line CL, and a top surface of the lower magnetic layer 110 may be in contact with the exchange coupling layer 120.

In an example, the lower magnetic layer 110 may have a perpendicular magnetic anisotropy (PMA). Each of the lower magnetic domains DM1 may have a magnetization direction MDf1, which is perpendicular to an interface between the lower magnetic layer 110 and the exchange coupling layer 120. The magnetization direction MDf1 of each of the lower magnetic domains DM1 may be perpendicular to the top surface CL_U of the conductive line CL. An adjacent pair of the lower magnetic domains DM1 may have magnetization directions MDf1 that are opposite to each other. Each of the lower magnetic domain walls DW1 may define a boundary between the pair of lower magnetic domains DM1 with the opposite magnetization directions MDf1.

The lower magnetic layer 110 may have a (111) texture of the face-centered cubic (FCC) structure or a (001) texture of the hexagonal closest packed (HCP) structure. In this case, the FCC (111) crystal facet or the HCP (001) crystal facet of the lower magnetic layer 110 may be parallel to the interface between the lower magnetic layer 110 and the exchange coupling layer 120. The lower magnetic layer 110 may have an FCC (111) crystal facet or the HCP (001) crystal facet at the interface between the lower magnetic layer 110 and the exchange coupling layer 120. The conductive line CL may expedite the growth of the FCC (111) crystal facet or the HCP (001) crystal facet of the lower magnetic layer 110. The lower magnetic layer 110 may include at least one of cobalt (Co), iron (Fe), and nickel (Ni), and in an implementation, it may further include at least one of palladium (Pd), platinum (Pt), gadolinium (Gd), and terbium (Tb). In an implementation, the lower magnetic layer 110 may include cobalt or cobalt alloy, and here, the cobalt alloy may include an alloy containing at least one of iron (Fe), nickel (Ni), palladium (Pd), platinum (Pt), gadolinium (Gd) and terbium (Tb) and cobalt.

The exchange coupling layer 120 may be configured to antiferromagnetically couple the lower magnetic layer 110 with the upper magnetic layer 140. The exchange coupling layer 120 may include a first non-magnetic metal (e.g., ruthenium (Ru), iridium (Ir), rhodium (Rh), tungsten (W), tantalum (Ta), or alloys thereof). A bottom surface of the exchange coupling layer 120 may be in contact with the lower magnetic layer 110, and a top surface of the exchange coupling layer 120 may be in contact with the spacer layer 130.

The spacer layer 130 may include a second non-magnetic metal (e.g., tungsten (W), tantalum (Ta), molybdenum (Mo), niobium (Nb), rhenium (Re), or alloys thereof). The spacer layer 130 may further include a magnetic element. In an implementation, the spacer layer 130 may include an alloy containing at least one of CoFeB, Co, Fe, and CoFe and the second non-magnetic metal. The spacer layer 130 may further include boron (B). In the case where a thermal treatment process is performed on the magnetic track line MTL, the spacer layer 130 may absorb boron (B) atoms diffused in the magnetic track line MTL.

A bottom surface of the spacer layer 130 may be in contact with the exchange coupling layer 120, and a top surface of the spacer layer 130 may be in contact with the upper magnetic layer 140. The spacer layer 130 may block the FCC (111) texture or HCP (001) texture of the underlying layers (e.g., the lower magnetic layer 110 and the exchange coupling layer 120) and may expedite the growth of the BCC (001) crystal facet of the upper magnetic layer 140. The spacer layer 130 may be used to adjust the strength of the antiferromagnetic coupling between the lower magnetic layer 110 and the upper magnetic layer 140. As an example, in the case where a thickness of the spacer layer 130 in the second direction D2 increases, the strength of the antiferromagnetic coupling between the lower magnetic layer 110 and the upper magnetic layer 140 may decrease, and in the case where the thickness of the spacer layer 130 in the second direction D2 decreases, the strength of the antiferromagnetic coupling between the lower magnetic layer 110 and the upper magnetic layer 140 may increase.

The upper magnetic layer 140 may include upper magnetic domains DM2, which are arranged in the first direction D1, and upper magnetic domain walls DW2, which are provided between the upper magnetic domains DM2. Each of the upper magnetic domains DM2 may be a region, which is formed in the upper magnetic layer 140 and has a magnetic moment of the same or aligned direction, and each of the upper magnetic domain walls DW2 may be a boundary formed between the upper magnetic domains DM2, where the direction of the magnetic moment is changed. The upper magnetic domains DM2 and the upper magnetic domain walls DW2 may be alternately arranged in the first direction D1. The upper magnetic domains DM2 may be vertically overlapped with the lower magnetic domains DM1, respectively, in the second direction D2. A bottom surface of the upper magnetic layer 140 may be in contact with the spacer layer 130, and a top surface of the upper magnetic layer 140 may be in contact with the non-magnetic line 150.

The upper magnetic layer 140 may have a perpendicular magnetic anisotropy (PMA). Each of the upper magnetic domains DM2 may have a magnetization direction MDf2, which is perpendicular to an interface between the upper magnetic layer 140 and the non-magnetic line 150. The magnetization direction MDf2 of each of the upper magnetic domains DM2 may be perpendicular to the top surface CL_U of the conductive line CL. A pair of the upper magnetic domains DM2, which are closest to each other, may have magnetization directions MDf2 that are opposite to each other. Each of the upper magnetic domain walls DW2 may define a boundary between the pair of upper magnetic domains DM2 with the opposite magnetization directions MDf2.

The upper magnetic domains DM2 may be vertically overlapped with the lower magnetic domains DM1, respectively, in the second direction D2, and the upper and lower magnetic domains DM2 and DM1 may be antiferromagnetically coupled with each other through the exchange coupling layer 120. The magnetization direction MDf2 of each of the upper magnetic domains DM2 may be anti-parallel to the magnetization direction MDf1 of a corresponding one of the lower magnetic domains DM1.

The upper magnetic layer 140 may have a (001) texture of the body-centered cubic (BCC) structure. The upper magnetic layer 140 may have the BCC lattice structure and may have a BCC (001) texture. In this case, the BCC (001) crystal facet of the upper magnetic layer 140 may be parallel to the interface between the upper magnetic layer 140 and the non-magnetic line 150. The upper magnetic layer 140 may have a BCC (001) crystal facet at the interface between the upper magnetic layer 140 and the non-magnetic line 150. The spacer layer 130 may expedite the growth of the BCC (001) crystal facet of the upper magnetic layer 140. The upper magnetic layer 140 may include at least one of cobalt (Co), iron (Fe), and nickel (Ni) and may further include boron (B). In an implementation, the upper magnetic layer 140 may include CoFeB or FeB.

The non-magnetic line 150 may include a metal oxide material. In an implementation, the non-magnetic line 150 may include at least one of magnesium oxide, titanium oxide, aluminum oxide, magnesium aluminum oxide, magnesium gallium oxide, magnesium-zinc oxide, or magnesium-boron oxide.

The non-magnetic line 150 may have a (001) texture of the NaCl structure. The non-magnetic line 150 may have the NaCl lattice structure, and the (001) crystal facet of the non-magnetic line 150 may be parallel to the interface between the upper magnetic layer 140 and the non-magnetic line 150. The non-magnetic line 150 may have a (001) crystal facet at the interface between the upper magnetic layer 140 and the non-magnetic line 150. The (001) crystal facet of the upper magnetic layer 140 and the (001) crystal facet of the non-magnetic line 150 may be in contact with each other and may form an interface therebetween. The non-magnetic line 150 may be referred to as a tunnel barrier line.

The reading device 200 may include a reference magnetic pattern 210 on the non-magnetic line 150 and an electrode pattern 220 on the reference magnetic pattern 210. The reference magnetic pattern 210 may be disposed between the non-magnetic line 150 and the electrode pattern 220. The reading device 200 may be overlapped with a corresponding one of the upper magnetic domains DM2 and a corresponding one of the lower magnetic domains DM1 vertically (e.g., in the second direction D2).

In an example, the reference magnetic pattern 210 may have a perpendicular magnetic anisotropy (PMA). The reference magnetic pattern 210 may have a magnetization direction MDp, which is perpendicular to an interface between the reference magnetic pattern 210 and the non-magnetic line 150, and the magnetization direction MDp of the reference magnetic pattern 210 may be fixed to a specific direction. The reference magnetic pattern 210 may include at least one of cobalt (Co), iron (Fe), and nickel (Ni) and may further include at least one of non-magnetic materials (e.g., boron (B), zinc (Zn), aluminum (Al), titanium (Ti), ruthenium (Ru), tantalum (Ta), silicon (Si), silver (Ag), gold (Au), copper (Cu), carbon (C), and nitrogen (N)). The reference magnetic pattern 210 may include at least one of i) perpendicular magnetic materials (e.g., CoFeTb, CoFeGd, and CoFeDy), ii) perpendicular magnetic materials with L1₀ structure, iii) CoPt-based materials with hexagonal-close-packed structure, or iv) perpendicular magnetic structures. The perpendicular magnetic material with the L1₀ structure may include at least one of L1₀ FePt, L1₀ FePd, L1₀ CoPd, or L1₀ CoPt. The perpendicular magnetic structures may include magnetic and non-magnetic layers that are alternatingly and repeatedly stacked. For example, the perpendicular magnetic structures may include at least one of (Co/Pt)n, (CoFe/Pt)n, (CoFe/Pd)n, (Co/Pd)n, (Co/Ni)n, (CoNi/Pt)n, (CoCr/Pt) n or (CoCr/Pd)n, where n is the number of pairs of the stacked layers. The reference magnetic pattern 210 may be formed of or include at least one of CoFeB or Co-based Heusler alloys.

The reference magnetic pattern 210 may be overlapped with a corresponding one of the upper magnetic domains DM2 and a corresponding one of the lower magnetic domains DM1 vertically (e.g., in the second direction D2). The reference magnetic pattern 210, the corresponding upper magnetic domain DM2, and the corresponding lower magnetic domain DM1, which are vertically overlapped with each other, may constitute a magnetic tunnel junction.

The electrode pattern 220 may include a conductive material and may include at least one of metallic materials (e.g., copper, tungsten, or aluminum) and/or metal nitride materials (e.g., tantalum nitride, titanium nitride, or tungsten nitride).

In the case where the current Ic flows through the conductive line CL in the first direction D1 or in the opposite direction of the first direction D1, the lower magnetic domain walls DW1 in the lower magnetic layer 110 may be moved in the first direction D1. The movement of the lower magnetic domain walls DW1 may be caused by a spin orbit torque and Dzyaloshinskii-Moriya interaction (DMI), which occur at an interface between the conductive line CL and the lower magnetic layer 110. The direction of the movement of the lower magnetic domain walls DW1 may depend on the chirality of the lower magnetic domain walls DW1. Since the lower magnetic domain walls DW1 in the lower magnetic layer 110 are moved in the first direction D1, the upper magnetic domain walls DW2 in the upper magnetic layer 140 may also be moved in the first direction D1. The movement of the upper magnetic domain walls DW2 may result from an antiferromagnetic coupling between the lower magnetic layer 110 and the upper magnetic layer 140.

Since the lower magnetic layer 110 has the FCC (111) texture or the HCP (001) texture, the strength of the antiferromagnetic coupling between the lower magnetic layer 110 and the upper magnetic layer 140 may be increased. Thus, the lower and upper magnetic domain walls DW1 and DW2 in the magnetic track line MTL may be moved with increased efficiency. This means that it is possible to reduce the current Ic required to move the lower and upper magnetic domain walls DW1 and DW2 in the magnetic track line MTL.

During the reading operation, a reading current Iread may flow through the magnetic tunnel junction including the reference magnetic pattern 210, the corresponding upper magnetic domain DM2, and the corresponding lower magnetic domain DM1, which are vertically overlapped with each other. A resistance state of the magnetic tunnel junction may be detected by the reading current Iread. For example, by measuring the reading current Iread, it may be possible to determine whether the magnetic tunnel junction is in a high or low resistance state. The resistance state of the magnetic tunnel junction may be used to determine whether data stored in the magnetic track line MTL is 0 or 1.

Since the upper magnetic layer 140 has the BCC (001) texture, the magnetic anisotropy of the upper magnetic layer 140, which is induced by the coupling between the upper magnetic layer 140 and the non-magnetic line 150, may be improved. Thus, the tunnel magnetoresistance ratio (TMR) of the magnetic tunnel junction may be improved, and this may make it possible to stably perform the reading operation through the reading device 200.

In an example, the lower magnetic layer 110 and the upper magnetic layer 140 may be antiferromagnetically coupled with each other by the exchange coupling layer 120. Since the lower magnetic layer 110 has the FCC (111) texture or the HCP (001) texture, the strength of the antiferromagnetic coupling between the lower magnetic layer 110 and the upper magnetic layer 140 may be increased, and this may make it possible to move the lower and upper magnetic domain walls DW1 and DW2 in the magnetic track line MTL more efficiently. The spacer layer 130 may be interposed between the exchange coupling layer 120 and the upper magnetic layer 140. The spacer layer 130 may block the FCC (111) texture or HCP (001) texture of the lower magnetic layer 110 and may expedite the crystal growth of the upper magnetic layer 140 with the BCC (001) texture. Since the upper magnetic layer 140 has the BCC (001) texture, a tunnel magnetoresistance ratio of the magnetic tunnel junction may be improved, and as a result, the reading operation by the reading device 200 may be performed in a more stable manner.

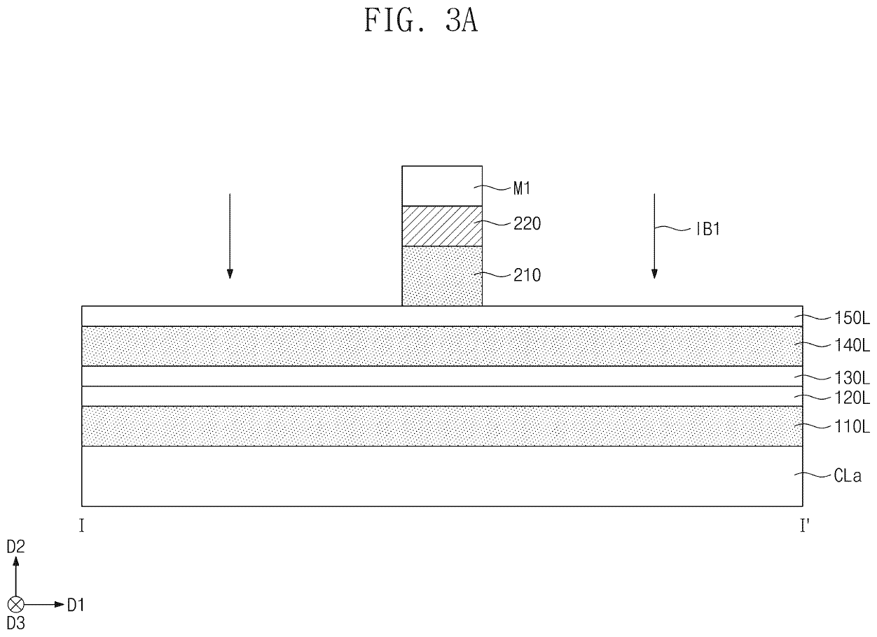

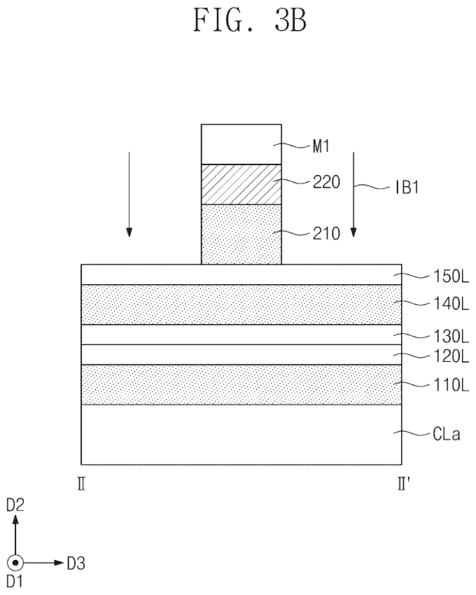

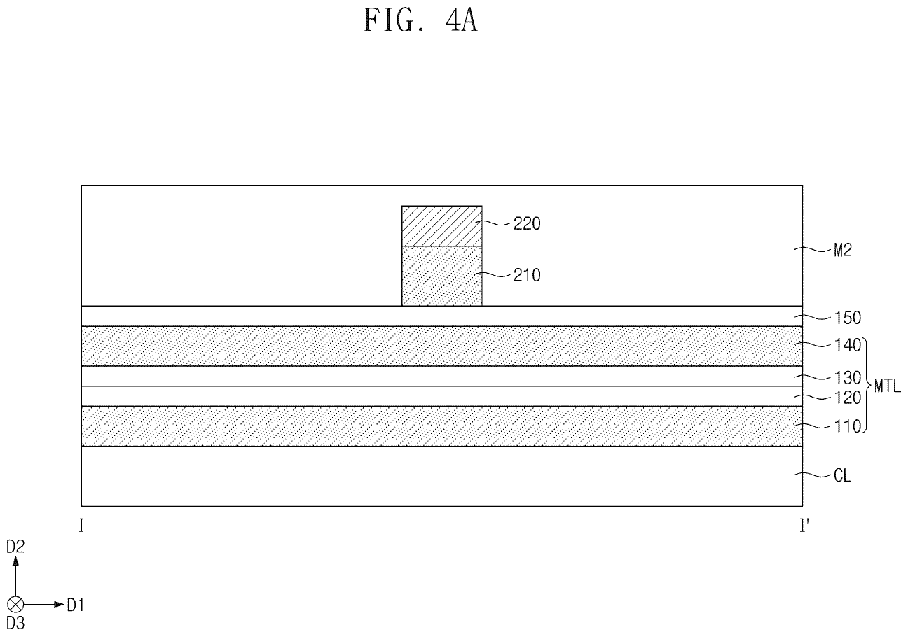

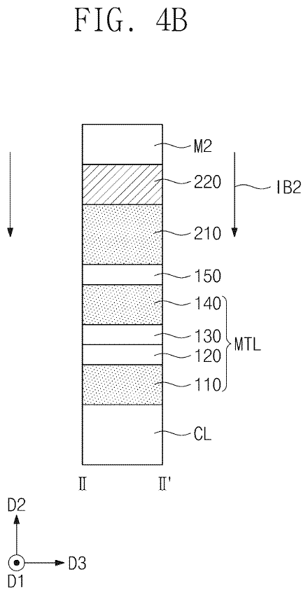

FIGS. 3A, 3B, 4A, and 4B are sectional views illustrating a method of fabricating an example magnetic memory device. FIGS. 3A and 4A are sectional views corresponding to the line I-I′ of FIG. 1, and FIGS. 3B and 4B are sectional views corresponding to a line II-II′ of FIG. 1. For the sake of brevity, the same elements as that in the magnetic memory device described with reference to FIGS. 1 and 2 may be identified by the same reference number without repeating an overlapping description.

Referring to FIGS. 3A and 3B, a preliminary lower magnetic layer 110L, a preliminary exchange coupling layer 120L, a preliminary spacer layer 130L, a preliminary upper magnetic layer 140L, and a non-magnetic thin film 150L may be sequentially stacked on a conductive thin film CLa. The conductive thin film Cla, the preliminary lower magnetic layer 110L, the preliminary exchange coupling layer 120L, the preliminary spacer layer 130L, the preliminary upper magnetic layer 140L, and the non-magnetic thin film 150L may be formed by a chemical vapor deposition process or a physical vapor deposition process (e.g., a sputtering deposition process).

A reference magnetic pattern 210 and an electrode pattern 220 may be formed on the non-magnetic thin film 150L. In an implementation, the formation of the reference magnetic pattern 210 and the electrode pattern 220 may include sequentially depositing a reference magnetic layer and an electrode layer on the non-magnetic thin film 150L, forming a first mask pattern M1 on the electrode layer to define a planar shape of the reference magnetic pattern 210, and performing a first etching process IB1 using the first mask pattern M1 as an etch mask to etch the reference magnetic layer and the electrode layer. The reference magnetic layer and the electrode layer may be formed by a chemical vapor deposition process or a physical vapor deposition method (e.g., a sputtering deposition process). In an implementation, the first mask pattern M1 may be a photoresist pattern or a hard mask pattern. The first etching process IB1 may be an ion beam etching process, for example, using an inert ion (e.g., argon (Ar)). In an implementation, a metal element in the non-magnetic thin film 150L may be used as an element generating an end-point detection (EPD) signal in the first etching process IB1. The first etching process IB1 may be performed to expose the non-magnetic thin film 150L, and the preliminary upper magnetic layer 140L may not be exposed during the first etching process IB1.

In the case where the first etching process IB1 is performed using the EPD signal generated when the metal element in the non-magnetic thin film 150L is detected, it may be possible to sufficiently etch the reference magnetic layer and the electrode layer and easily expose the non-magnetic thin film 150L. Thus, it may be possible to prevent unetched portions or residues of the reference magnetic layer and the electrode layer from being left on the non-magnetic thin film 150L. In addition, the preliminary upper magnetic layer 140L may not be exposed to the outside during the first etching process IB1, and thus, it may be possible to prevent the preliminary upper magnetic layer 140L from being damaged by the first etching process IB1.

Referring to FIGS. 4A and 4B, the first mask pattern M1 may be removed, after the formation of the reference magnetic pattern 210 and the electrode pattern 220. In an implementation, the first mask pattern M1 may be removed using an ashing and/or a strip process.

A second mask pattern M2 may be formed on the non-magnetic thin film 150L to cover the reference magnetic pattern 210 and the electrode pattern 220. The second mask pattern M2 may have a line shape extending in the first direction D1. In an implementation, the second mask pattern M2 may be a photoresist pattern or a hard mask pattern.

The non-magnetic thin film 150L, the preliminary upper magnetic layer 140L, the preliminary spacer layer 130L, the preliminary exchange coupling layer 120L, the preliminary lower magnetic layer 110L, and the conductive thin film Cla may be sequentially etched by a second etching process IB2 using the second mask pattern M2 as an etch mask. Accordingly, a conductive line CL, a lower magnetic layer 110, an exchange coupling layer 120, a spacer layer 130, an upper magnetic layer 140, and a non-magnetic line 150 may be formed. The second etching process IB2 may be an ion beam etching process, and in an implementation, it may be an ion beam etching process using an inert ion (e.g., argon (Ar)).

Each of the conductive line CL, the lower magnetic layer 110, the exchange coupling layer 120, the spacer layer 130, the upper magnetic layer 140, and the non-magnetic line 150 may be a line-shaped structure extended in the first direction D1. The lower magnetic layer 110, the exchange coupling layer 120, the spacer layer 130, and the upper magnetic layer 140 may constitute a magnetic track line MTL. The second mask pattern M2 may be removed after the formation of the conductive line CL, the magnetic track line MTL, and the non-magnetic line 150. In an implementation, the second mask pattern M2 may be removed by an ashing and/or a strip process.

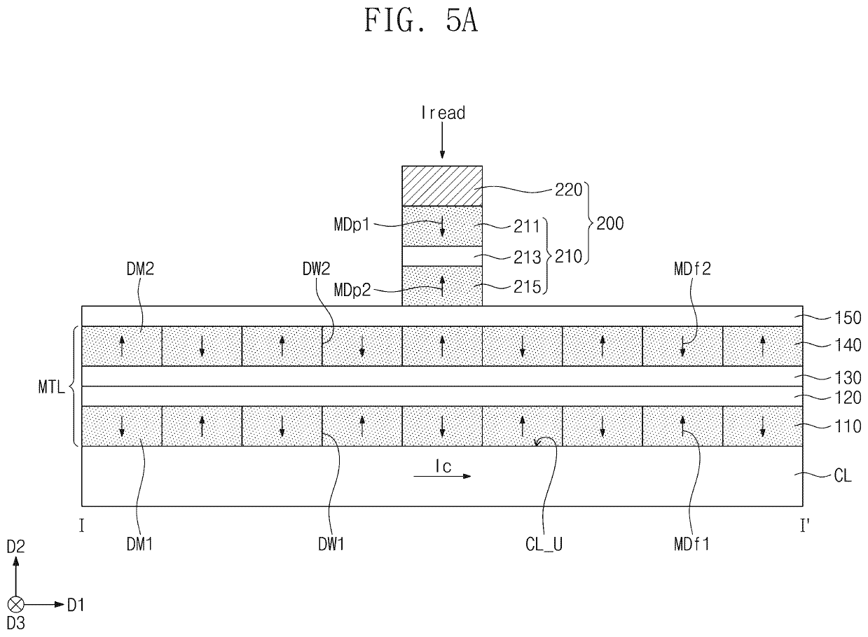

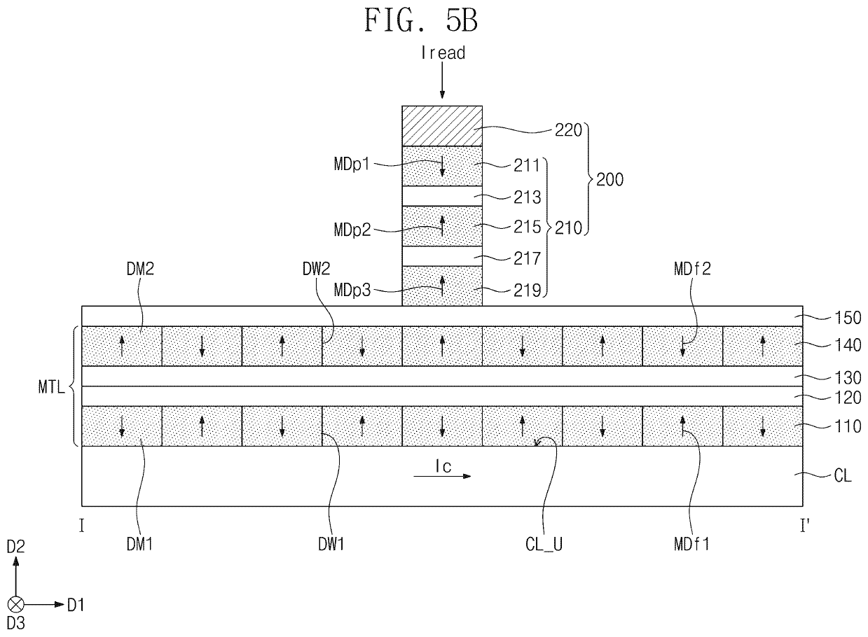

FIGS. 5A and 5B are sectional views, which are taken along a line I-I′ of FIG. 1 to illustrate an example magnetic memory device. For the sake of brevity, elements, which are different from those in the magnetic memory device described with reference to FIGS. 1 and 2, will be mainly described below.

Referring to FIGS. 5A and 5B, the reading device 200 may include a reference magnetic pattern 210 on the non-magnetic line 150 and an electrode pattern 220 on the reference magnetic pattern 210. The reference magnetic pattern 210 may be disposed between the non-magnetic line 150 and the electrode pattern 220.

Referring to FIG. 5A, the reference magnetic pattern 210 may include a first pinned pattern 211 between the non-magnetic line 150 and the electrode pattern 220, a second pinned pattern 215 between the non-magnetic line 150 and the first pinned pattern 211, and a first non-magnetic pattern 213 between the first and second pinned patterns 211 and 215.

Each of the first and second pinned patterns 211 and 215 may have a perpendicular magnetic anisotropy (PMA). The first pinned pattern 211 may have a magnetization direction MDp1, which is perpendicular to an interface between the non-magnetic line 150 and the second pinned pattern 215, and the magnetization direction MDp1 of the first pinned pattern 211 may be fixed to a specific direction. The second pinned pattern 215 may have a magnetization direction MDp2, which is perpendicular to the interface between the non-magnetic line 150 and the second pinned pattern 215, and the magnetization direction MDp2 of the second pinned pattern 215 may be fixed to be antiparallel to the magnetization direction MDp1 of the first pinned pattern 211. The second pinned pattern 215 may be antiferromagnetically coupled with the first pinned pattern 211 by the first non-magnetic pattern 213. That is, the first non-magnetic pattern 213 may be configured to antiferromagnetically couple the first and second pinned patterns 211 and 215 with each other.

Each of the first and second pinned patterns 211 and 215 may include at least one of cobalt (Co), iron (Fe), and nickel (Ni) and may further include at least one of non-magnetic materials (e.g., boron (B), zinc (Zn), aluminum (Al), titanium (Ti), ruthenium (Ru), tantalum (Ta), silicon (Si), silver (Ag), gold (Au), copper (Cu), carbon (C), and nitrogen (N)). Each of the first and second pinned patterns 211 and 215 may include at least one of i) perpendicular magnetic materials (e.g., CoFeTb, CoFeGd, and CoFeDy), ii) perpendicular magnetic materials with L1₀ structure, iii) CoPt-based materials with hexagonal-close-packed structure, or iv) perpendicular magnetic structures. The perpendicular magnetic material with the L1₀ structure may include at least one of L1₀ FePt, L1₀ FePd, L1₀ CoPd, or L1₀ CoPt. The perpendicular magnetic structures may include magnetic and non-magnetic layers that are alternatingly and repeatedly stacked. For example, the perpendicular magnetic structures may include at least one of (Co/Pt)n, (CoFe/Pt)n, (CoFe/Pd)n, (Co/Pd)n, (Co/Ni)n, (CoNi/Pt)n, (CoCr/Pt) n or (CoCr/Pd)n, where n is the number of pairs of the stacked layers. Each of the first and second pinned patterns 211 and 215 may be formed of or include at least one of CoFeB or Co-based Heusler alloys.

The first non-magnetic pattern 213 may include a non-magnetic metal material (e.g., ruthenium (Ru), iridium (Ir), rhodium (Rh), tungsten (W), tantalum (Ta), or alloys thereof).

Referring to FIG. 5B, the reference magnetic pattern 210 may further include a third pinned pattern 219 between the non-magnetic line 150 and the second pinned pattern 215 and a second non-magnetic pattern 217 between the second pinned pattern 215 and the third pinned pattern 219.

The third pinned pattern 219 may have a perpendicular magnetic anisotropy (PMA). The third pinned pattern 219 may have a magnetization direction MDp3, which is perpendicular to an interface between the non-magnetic line 150 and the third pinned pattern 219, and the magnetization direction MDp3 of the third pinned pattern 219 may be fixed to be parallel to the magnetization direction MDp2 of the second pinned pattern 215. The third pinned pattern 219 may be ferromagnetically coupled with the second pinned pattern 215 by the second non-magnetic pattern 217. The second non-magnetic pattern 217 may be configured to ferromagnetically couple the second pinned pattern 215 with the third pinned pattern 219.

The third pinned pattern 219 may include at least one of cobalt (Co), iron (Fe), and nickel (Ni) and may further include at least one of non-magnetic materials (e.g., boron (B), zinc (Zn), aluminum (Al), titanium (Ti), ruthenium (Ru), tantalum (Ta), silicon (Si), silver (Ag), gold (Au), copper (Cu), carbon (C), and nitrogen (N)). In an implementation, the third pinned pattern 219 may include CoFeB. The second non-magnetic pattern 217 may include a non-magnetic metal material (e.g., ruthenium (Ru), iridium (Ir), rhodium (Rh), tungsten (W), tantalum (Ta), or alloys thereof).

Except for the afore-described differences, the magnetic memory device according to the present implementation may be substantially the same as the magnetic memory device described with reference to FIGS. 1 and 2.

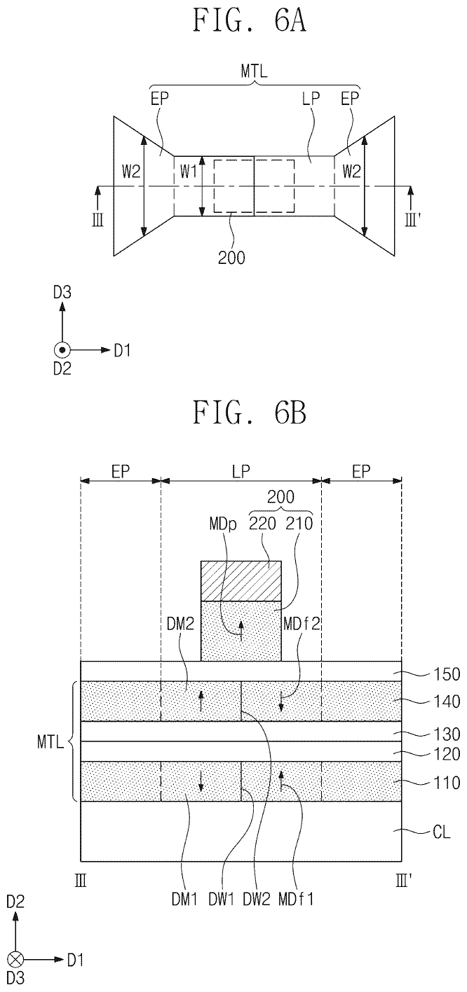

FIG. 6A is a plan view illustrating an example magnetic memory device, and FIG. 6B is a sectional view taken along a line III-III′ of FIG. 6A. For the sake of brevity, elements, which are different from those in the magnetic memory device described with reference to FIGS. 1 and 2, will be mainly described below.

Referring to FIGS. 6A and 6B, the magnetic track line MTL may include a line portion LP, which is extended in the first direction D1, and end portions EP, which are connected to opposite ends of the line portion LP. The end portions EP may be spaced apart from each other in the first direction D1, with the line portion LP interposed therebetween. The line portion LP may have a first width W1 in the third direction D3, and each of the end portions EP may have a second width W2 in the third direction D3. The second width W2 may be larger than the first width W1. The second width W2 of each of the end portions EP may increase, as a distance from the line portion LP (e.g., in the first direction D1 or the opposite direction thereof) increases.

The lower magnetic layer 110 of the line portion LP may include a pair of lower magnetic domains DM1, which are arranged in the first direction D1, and a lower magnetic domain wall DW1, which is formed between the pair of lower magnetic domains DM1. The pair of lower magnetic domains DM1 may have magnetization directions MDf1 that are opposite to each other. The upper magnetic layer 140 of the line portion LP may include a pair of upper magnetic domains DM2, which are arranged in the first direction D1, and an upper magnetic domain wall DW2, which is formed between the pair of upper magnetic domains DM2. The pair of upper magnetic domains DM2 may have magnetization directions MDf2 that are opposite to each other. The pair of upper magnetic domains DM2 may be vertically overlapped with the pair of lower magnetic domains DM1, respectively, in the second direction D2, and the pair of upper magnetic domains DM2 and the pair of lower magnetic domains DM1 may be antiferromagnetically coupled with each other through the exchange coupling layer 120. The magnetization direction MDf2 of each of the upper magnetic domains DM2 may be antiparallel to the magnetization direction MDf1 of a corresponding one of the lower magnetic domains DM1.

The reading device 200 may be disposed on the line portion LP of the magnetic track line MTL. The reading device 200 may be vertically (e.g., in the second direction D2) overlapped with a corresponding one of the upper magnetic domains DM2 and a corresponding one of the lower magnetic domains DM1 to form a magnetic tunnel junction. The reading device 200 may detect a resistance state of the magnetic tunnel junction or may determine whether the magnetic tunnel junction is in a high or low resistance state. The magnetic memory device according to the present implementation may serve as a single-bit memory device.

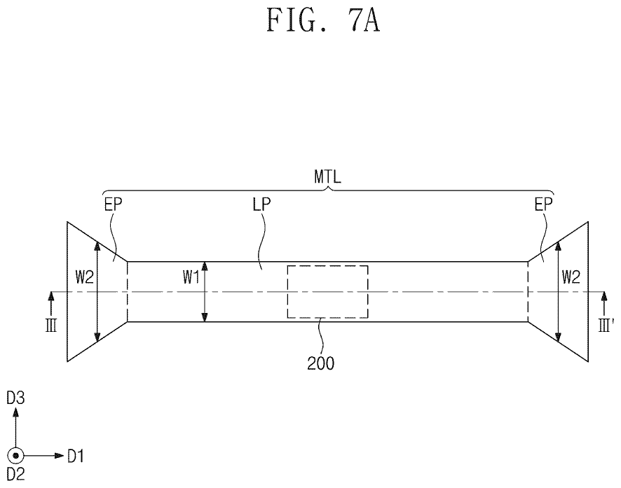

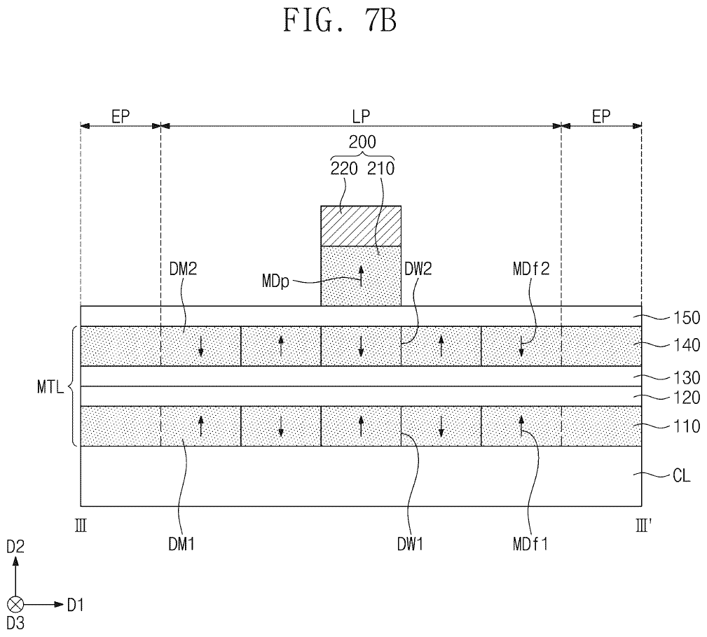

FIG. 7A is a plan view illustrating an example magnetic memory device, and FIG. 7B is a sectional view taken along a line III-III′ of FIG. 7A. For the sake of brevity, elements, which are different from those in the magnetic memory device described with reference to FIGS. 1 and 2, will be mainly described below.

Referring to FIGS. 7A and 7B, the magnetic track line MTL may include a line portion LP, which is extended in the first direction D1, and end portions EP, which are connected to opposite ends of the line portion LP. The end portions EP may be spaced apart from each other in the first direction D1, with the line portion LP interposed therebetween. The line portion LP may have a first width W1 in the third direction D3, and each of the end portions EP may have a second width W2 in the third direction D3. The second width W2 may be larger than the first width W1. The second width W2 of each of the end portions EP may increase, as a distance from the line portion LP (e.g., in the first direction D1 or the opposite direction thereof) increases.

The lower magnetic layer 110 of the line portion LP may include lower magnetic domains DM1, which are arranged in the first direction D1, and lower magnetic domain walls DW1, which are formed between the lower magnetic domains DM1. In an implementation, the number of the lower magnetic domains DM1 may be at least three. The lower magnetic domains DM1 and the lower magnetic domain walls DW1 may be alternately arranged in the first direction D1. A pair of the lower magnetic domains DM1, which are closest to each other, may have opposite magnetization directions MDf1. Each of the lower magnetic domain walls DW1 may define a boundary between the pair of the lower magnetic domains DM1 with the opposite magnetization directions MDf1.

The upper magnetic layer 140 of the line portion LP may include upper magnetic domains DM2, which are arranged in the first direction D1, and upper magnetic domain walls DW2, which are placed between the upper magnetic domains DM2. The number of the upper magnetic domains DM2 may be at least three. The upper magnetic domains DM2 and the upper magnetic domain walls DW2 may be alternately arranged in the first direction D1. A pair of the upper magnetic domains DM2, which are closest to each other, may have magnetization directions MDf2 that are opposite to each other. Each of the upper magnetic domain walls DW2 may define a boundary between the pair of upper magnetic domains DM2 with the opposite magnetization directions MDf2. The upper magnetic domains DM2 may be vertically overlapped with the lower magnetic domains DM1, respectively, in the second direction D2, and the upper and lower magnetic domains DM2 and DM1 may be antiferromagnetically coupled with each other through the exchange coupling layer 120. The magnetization direction MDf2 of each of the upper magnetic domains DM2 may be anti-parallel to the magnetization direction MDf1 of a corresponding one of the lower magnetic domains DM1.

The reading device 200 may be disposed on the line portion LP of the magnetic track line MTL. The reading device 200 may be vertically (e.g., in the second direction D2) overlapped with a corresponding one of the upper magnetic domains DM2 and a corresponding one of the lower magnetic domains DM1 to form a magnetic tunnel junction. The reading device 200 may detect a resistance state of the magnetic tunnel junction or may determine whether the magnetic tunnel junction is in a high or low resistance state. The magnetic memory device according to the present implementation may be used as a multi-bit memory device.

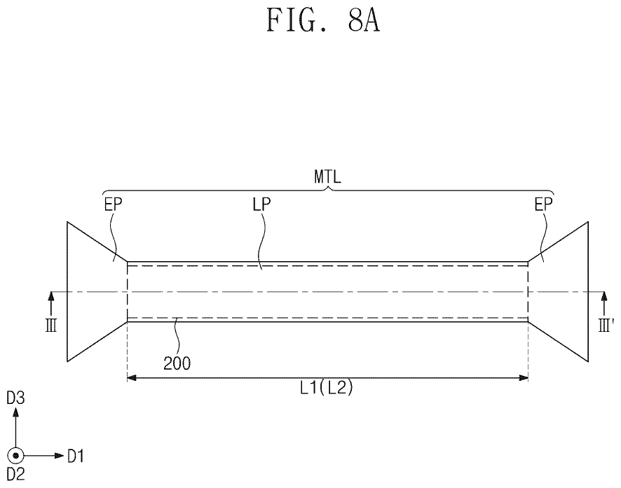

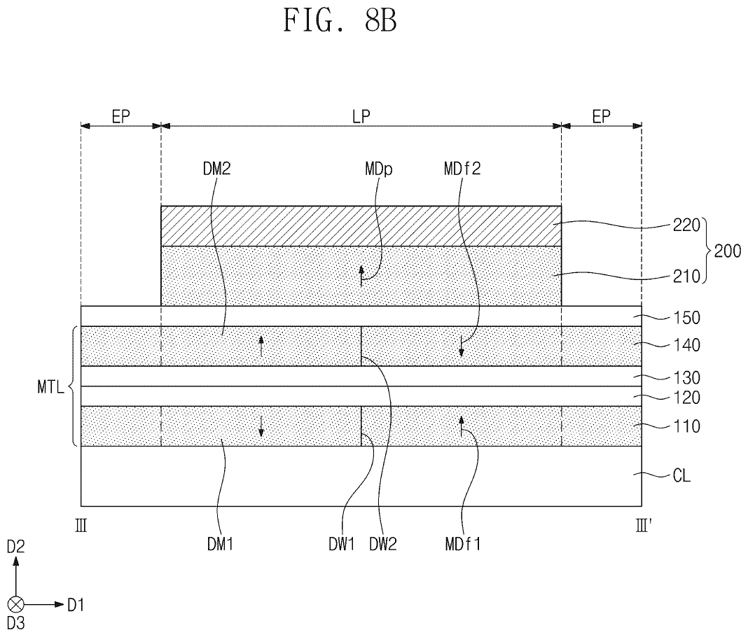

FIG. 8A is a plan view illustrating an example magnetic memory device, and FIG. 8B is a sectional view taken along a line III-III′ of FIG. 8A. For the sake of brevity, elements, which are different from those in the magnetic memory devices described with reference to FIGS. 6A, 6B, 7A, and 7B, will be mainly described below.

Referring to FIGS. 8A and 8B, the line portion LP of the magnetic track line MTL may have a first length L1 in the first direction D1, and the reading device 200 may have a second length L2 in the first direction D1. In the present implementation, the second length L2 of the reading device 200 may be substantially equal to the first length L1 of the line portion LP. The reading device 200 may be a line-shaped structure extended in the first direction D1. The reading device 200 may be overlapped with the line portion LP of the magnetic track line MTL vertically (e.g., in the second direction D2) and may not be overlapped with the end portions EP of the magnetic track line MTL vertically (e.g., in the second direction D2).

In an implementation, the magnetic track line MTL may be configured to have substantially the same features as the magnetic track line MTL described with reference to FIGS. 6A and 6B. In this case, the magnetic memory device according to the present implementation may serve as a single-bit memory device.

In an implementation, the magnetic track line MTL may be configured to have substantially the same features as the magnetic track line MTL described with reference to FIGS. 7A and 7B. In this case, the magnetic memory device according to the present implementation may serve as a multi-bit memory device.

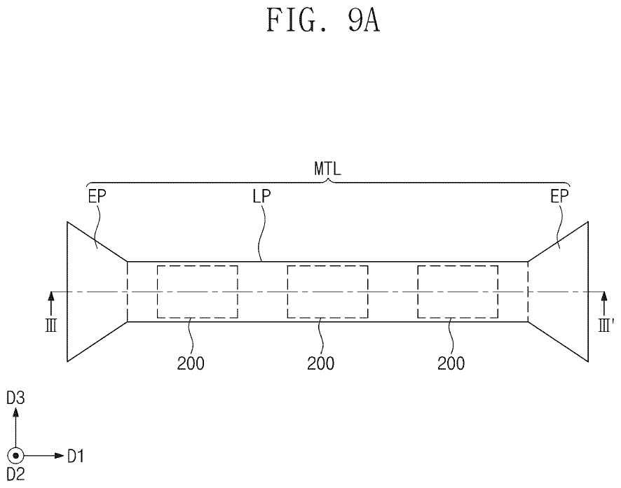

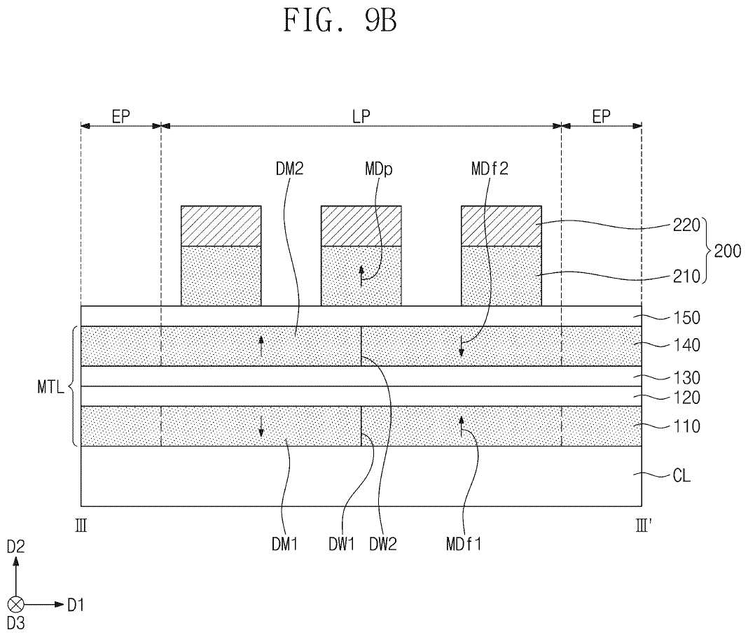

FIG. 9A is a plan view illustrating a magnetic memory device, and FIG. 9B is a sectional view taken along a line III-III′ of FIG. 9A. For the sake of brevity, elements, which are different from those in the magnetic memory devices described with reference to FIGS. 6A, 6B, 7A, and 7B, will be mainly described below.

Referring to FIGS. 9A and 9B, a plurality of reading devices 200 may be provided on the line portion LP of the magnetic track line MTL. Each of the reading devices 200 may be overlapped with the line portion LP vertically (e.g., in the second direction D2). In an implementation, the reading devices 200 may be electrically separated from each other and may be configured to perform their own reading operations independently. In an implementation, the reading devices 200 may be connected to each other in parallel and may be configured to perform the reading operation in parallel.

In an implementation, the magnetic track line MTL may be configured to have substantially the same features as the magnetic track line MTL described with reference to FIGS. 6A and 6B. In this case, the magnetic memory device according to the present implementation may serve as a single-bit memory device.

In an implementation, the magnetic track line MTL may be configured to have substantially the same features as the magnetic track line MTL described with reference to FIGS. 7A and 7B. In this case, the magnetic memory device according to the present implementation may serve as a multi-bit memory device.

A magnetic track line may have a synthetic antiferromagnetic structure, in which a lower magnetic layer and an upper magnetic layer are antiferromagnetically coupled with each other by an exchange coupling layer therebetween, and may include a spacer layer interposed between the exchange coupling layer and the upper magnetic layer. The lower magnetic layer may have an FCC (111) texture or an HCP (001) texture, and in this case, the strength of the antiferromagnetic coupling between the lower magnetic layer and the upper magnetic layer may be increased. This may make it possible to efficiently move magnetic domains in the magnetic track line (e.g., lower magnetic domains in the lower magnetic layer and upper magnetic domains in the upper magnetic layer). The spacer layer may block the FCC (111) texture or HCP (001) texture of the lower magnetic layer and may expedite the crystal growth of the upper magnetic layer. In this case, the upper magnetic layer may have a BCC (001) texture. Since the upper magnetic layer has the BCC (001) texture, a magnetic tunnel junction, which is provided as a reading device, may have improved tunnel magnetoresistance characteristics.

In the magnetic memory device, it may be possible to achieve high efficiency of the domain movement in the magnetic track line and to realize improved tunnel magnetoresistance characteristics of the magnetic tunnel junction serving as the reading device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been particularly shown and described, it will be understood by one of ordinary skill in the art that variations in form and detail may be made therein without departing from the spirit and scope of the attached claims.

What is claimed is:

1. A magnetic memory device, comprising:
a conductive line extended in a first direction;
a magnetic track line provided on the conductive line and extended in the first direction; and
a non-magnetic line provided on the magnetic track line and extended in the first direction,
wherein the magnetic track line comprises:
a lower magnetic layer and an upper magnetic layer stacked on the conductive line;
an exchange coupling layer between the lower and upper magnetic layers; and
a spacer layer between the exchange coupling layer and the upper magnetic layer,
wherein the exchange coupling layer is in contact with a bottom surface of the spacer layer, and
the lower and upper magnetic layers are antiferromagnetically coupled with each other by the exchange coupling layer.

2. The magnetic memory device of claim 1, wherein a face-centered cubic structure (111) crystal facet of the lower magnetic layer is parallel to an interface between the lower magnetic layer and the exchange coupling layer.

3. The magnetic memory device of claim 1, wherein a body-centered cubic structure (001) crystal facet of the upper magnetic layer is parallel to an interface between the upper magnetic layer and the non-magnetic line.

4. The magnetic memory device of claim 1, wherein the lower magnetic layer comprises:
lower magnetic domains arranged in the first direction, and
lower magnetic domain walls placed between the lower magnetic domains,
wherein the upper magnetic layer comprises:
upper magnetic domains arranged in the first direction, and
upper magnetic domain walls placed between the upper magnetic domains, and
wherein the upper magnetic domains vertically overlap with the lower magnetic domains, respectively.

5. The magnetic memory device of claim 1, wherein the spacer layer comprises a non-magnetic metal element.

6. The magnetic memory device of claim 1, wherein the non-magnetic line comprises metal oxide.

7. The magnetic memory device of claim 1, further comprising a reference magnetic pattern on the non-magnetic line,
wherein the reference magnetic pattern has a magnetization direction that is fixed to a specific direction.

8. The magnetic memory device of claim 7, wherein the reference magnetic pattern comprises:
a first pinned pattern;
a second pinned pattern between the first pinned pattern and the non-magnetic line; and
a first non-magnetic pattern between the first pinned pattern and the second pinned pattern,
wherein the first pinned pattern and the second pinned pattern are antiferromagnetically coupled with each other by the first non-magnetic pattern.

9. The magnetic memory device of claim 7, wherein the lower magnetic layer comprises lower magnetic domains arranged in the first direction,
the upper magnetic layer comprises upper magnetic domains arranged in the first direction, and
the reference magnetic pattern vertically overlaps with a corresponding one of the lower magnetic domains and a corresponding one of the upper magnetic domains to thereby form a magnetic tunnel junction.

10. The magnetic memory device of claim 9, wherein the lower magnetic layer, the upper magnetic layer, and the reference magnetic pattern have a perpendicular magnetic anisotropy.

11. The magnetic memory device of claim 1, wherein the conductive line is configured to produce a spin orbit torque by a current flowing through the conductive line.

12. A magnetic memory device, comprising:
a conductive line extended in a first direction;
a magnetic track line provided on a top surface of the conductive line and extended in the first direction; and
a reference magnetic pattern on the magnetic track line,
wherein the magnetic track line comprises:
a lower magnetic layer and an upper magnetic layer stacked on the conductive line;
an exchange coupling layer between the lower and upper magnetic layers; and
a spacer layer between the exchange coupling layer and the upper magnetic layer,
wherein a bottom surface of the spacer layer is in contact with the exchange coupling layer,
a top surface of the spacer layer is in contact with the upper magnetic layer, and
the lower and upper magnetic layers are antiferromagnetically coupled with each other by the exchange coupling layer.

13. The magnetic memory device of claim 12, wherein the spacer layer contains a non-magnetic metal element.

14. The magnetic memory device of claim 12, wherein a face-centered cubic structure (111) crystal facet of the lower magnetic layer is parallel to an interface between the lower magnetic layer and the exchange coupling layer.

15. The magnetic memory device of claim 14, further comprising a non-magnetic line between the magnetic track line and the reference magnetic pattern,
wherein the upper magnetic layer is interposed between the spacer layer and the non-magnetic line, and
a body-centered cubic structure (001) crystal facet of the upper magnetic layer is parallel to an interface between the upper magnetic layer and the non-magnetic line.

16. The magnetic memory device of claim 15, wherein a face-centered cubic structure (001) crystal facet of the non-magnetic line is parallel to the interface between the upper magnetic layer and the non-magnetic line.

17. The magnetic memory device of claim 15, wherein the non-magnetic line is extended in the first direction to cover portions of the magnetic track line at both sides of the reference magnetic pattern.

18. The magnetic memory device of claim 12, wherein the lower magnetic layer comprises:
lower magnetic domains arranged in the first direction, and
lower magnetic domain walls placed between the lower magnetic domains,
wherein the upper magnetic layer comprises:
upper magnetic domains arranged in the first direction, and
upper magnetic domain walls placed between the upper magnetic domains, and
wherein the upper magnetic domains vertically overlap with the lower magnetic domains, respectively.

19. The magnetic memory device of claim 18, wherein the reference magnetic pattern has a fixed magnetization direction, and
the reference magnetic pattern vertically overlaps with a corresponding one of the lower magnetic domains and a corresponding one of the upper magnetic domains to thereby form a magnetic tunnel junction.

20. The magnetic memory device of claim 12, wherein the conductive line is configured to produce a spin orbit torque by a current flowing through the conductive line.
